(19) United States
(12) Patent Application Publication
(10) Pub. No.: US 2007/0103862 A1
(43) Pub. Date: May 10, 2007

(54) Chassis with positive pressure

(76) Inventors: David Costello, Ashburn, VA (US); Michael Perri, Fairfax, VA (US)

Correspondence Address: Steven M. Greenberg;Christopher & Weisberg, P.A., Suite 2040, 200 East Las Olas Boulevard, Fort Lauderdale, FL, 33301, US

(21) Appl. No.: 11/271,293

(22) Filed: Nov. 10, 2005

(51) Int. Cl. H05K 7/20

(52) U.S. Cl. 361/687; 361/695

(57) ABSTRACT

A chassis for an electronic device, such as a computer, includes a plurality of fans attached to a single face of the chassis with each of the fans directing a fluid into an interior of the chassis and towards a second face of the chassis. The second face of the chassis has a greatest total area of output of openings within the chassis, and a positive pressure exists between the interior of the chassis and an exterior of the chassis at all the output openings within the chassis. At least one detachable filter is disposed over the plurality of fans, and at least one hexagon-shaped bezel is disposed between the plurality of fans and the at least one filter.

### BACKGROUND OF THE INVENTION

1. Field of the Invention

The disclosure relates generally to a chassis for an electronic system and, more specifically, to a computer chassis for use in a dirty environment.

2. Description of the Related Art

Electronic systems, such as computers, are vulnerable to particulate matter. For example, particulate matter can prevent hard drives and/or optical drives from properly reading media. Additionally, particulate matter can build up on cooling devices, such as a heat sink, which decreases the efficiency of the cooling device. Issues related to particulate matter, however, do not arise often in relatively clean environments, such as a typical office or home. Furthermore, where uptime of the electronic system is of particular importance, one manner of addressing these issues has been to place the electronic system in a clean room.

The use of a clean room environment, however, is not feasible in many applications. For example, in a situation where a computer is used to control equipment on a factory floor, placing the computer in a clean room creates issues associated with connecting the computer to the equipment as well as easily accessing the computer while operating the equipment. Therefore, in many instances, it is desirable to place the electronic system, such as a computer, adjacent the equipment, even if the environment is filled with particulate matter.

One particular feature (i.e., the cooling fan) commonly found in computer chassis further exacerbates the problem of preventing particulate matter from entering the chassis of the computer. Although a common technique has been to place filters over the cooling fans, in most instances, there are many opening in the computer chassis, besides the location of the cooling fan, where particulate matter can enter the chassis. For example, a computer chassis commonly has seams along edges of adjacent pieces of the chassis in addition to holes, such as mounting holes, within the chassis. There are also several much larger openings within the chassis that are adapted to receive expansion cards, input/output connectors, etc. through which particulate matter can enter the chassis. As a result of these multitude of openings, a common computer chassis acts as a veritable sieve that allows particulate-laden air to enter the chassis.

Another solution to preventing particular matter from entering a computer is to simply make the chassis airtight. This solution, however, is not commonly adopted since the solution is often too expensive to be practicable. Furthermore, maintaining the integrity of any seals within the computer chassis can also be expensive. There is, therefore, a need for a low-cost chassis system for an electronic system that reduces the amount of particulate-laden air entering the chassis of the electronic system.

### BRIEF SUMMARY OF THE INVENTION

Embodiments of the invention address deficiencies of the art in respect to an electronic system chassis and provide a novel and non-obvious device for reducing the amount of particulate-laden air entering the chassis of the electronic system. In this regard, the chassis for an electronic device, such as a computer, includes a plurality of fans attached to a single face of the chassis with each of the fans directing a fluid into an interior of the chassis and towards a second face of the chassis. The second face of the chassis has a greatest total area of output openings within the chassis, and a positive pressure exists between the interior of the chassis and an exterior of the chassis at all the output openings within the chassis. At least one detachable filter is disposed over the plurality of fans, and at least one hexagon-shaped bezel is disposed between the plurality of fans and the at least one filter.

In certain aspects of the chassis, a percentage of a total area of the plurality of fans on the single face to a total area of the single face of which the fans are disposed may be greater than approximately 18.0%, and in other aspects, greater than 24.0%. An average velocity of the fluid exiting the chassis at the output openings may be greater than 9 ft/second, and in other aspects, greater than 12 ft/second. A percentage of a total area of all the output openings to a total area bounded by the chassis may be greater than 1.5%, and in other aspects, greater than 2.0%. A volume of the interior of the chassis may be less than 1.5 ft³.

Additional aspects of the invention will be set forth in part in the description which follows, and in part will be obvious from the description, or may be learned by practice of the invention. The aspects of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The accompanying drawings, which are incorporated in and constitute part of this specification, illustrate embodiments of the invention and together with the description, serve to explain the principles of the invention. The embodiments illustrated herein are presently preferred, it being understood, however, that the invention is not limited to the precise arrangements and instrumentalities shown, wherein:

FIG. 1A is a schematic illustration of a base of a chassis in accordance with the inventive arrangements;

FIG. 1B is a schematic illustration of a cover of a chassis in accordance with the inventive arrangements;

FIG. 2 is an enlarged view of a bezel; and

FIGS. 3A and 3B are respective front and rear view of a filter for covering cooling fans within the chassis.

### DETAILED DESCRIPTION OF THE INVENTION

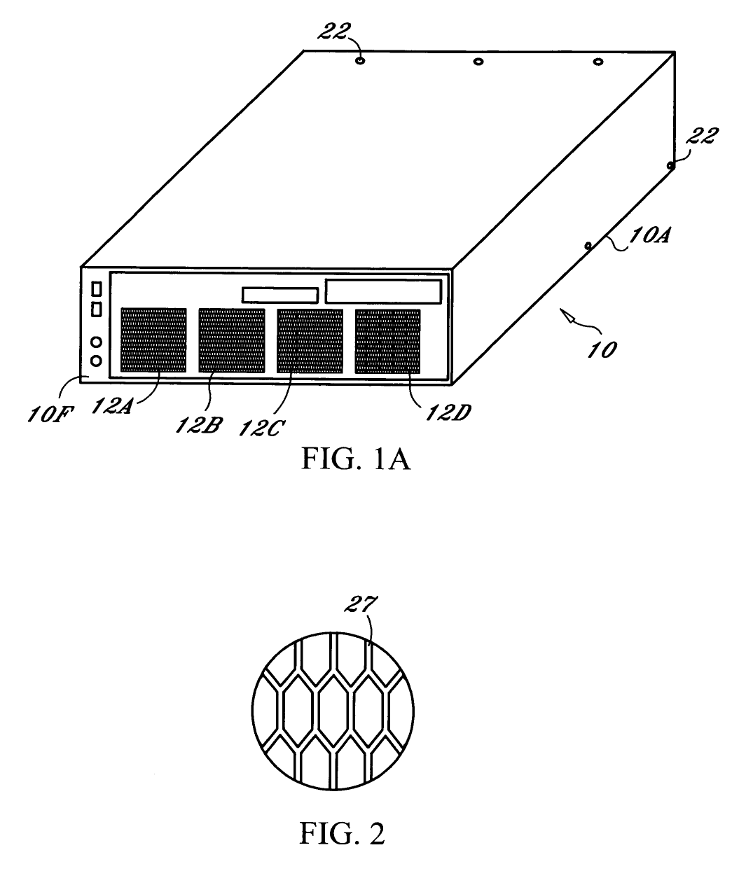

FIGS. 1A and 1B illustrate an electronic system chassis 10 for reducing particulate matter entering the chassis 10. As illustrated, the chassis 10 may include a chassis cover 10A and a chassis basis 10B that when combined define the external dimensions of the chassis 10 and bound the interior of the chassis 10. As is known in the art, many type of chassis configurations are known (e.g., the chassis may include a body and a hinged or sliding panel), and the present chassis 10 is not limited as to a particular configuration of defining the external dimensions of the chassis 10 and bounding an interior of the chassis 10. The chassis 10 is not limited as to the particular electronic system housed within the chassis 10.

Although not limited in this manner, an example of an electronic system housed within the chassis 10 is a computer system that may include, for example, a power supply 14, an optical drive 16, a floppy drive 18, a hard drive 20, and a mother board (not shown). Additionally, the chassis 10 may have an interior volume of less than 1.5 ft³.

A plurality of fans 12 (12A, 12B, 12C, 12D) are configured to introduce a cooling fluid, such as air, from the exterior of the chassis 10 into the interior of the chassis 10, and the plurality of fans 12 may be directly attached to the chassis 10. Although the plurality of fans 12 may be located on differing faces of the chassis 10, in one aspect of the chassis 10, each of the fans 12 are located on a common face of the chassis 10.

The fans 12 may also be located on a face of the chassis 10 opposite a face of the chassis 10 having a greatest surface area of openings within the chassis 10. By locating the fans 12 on a face of the chassis 10 opposite a face of the chassis 10 having a greatest surface area of openings a more direct path of air can be provided from the fans 12 to the greatest surface area of openings within the chassis 10. In this manner, a propensity for “hot spots” (i.e., areas of reduced air circulation) to develop within the interior of the chassis 10 can be reduced.

Typically, the rear face 10R of the chassis 10 has a greater surface area of openings within the chassis 10. For example, the rear face 10R commonly includes expansion card slots 24 and a slot 26 to accept the I/O panel connectors of a mother board (not shown). In contrast, the top, bottom, and side faces of the chassis 10 typically have few openings, such as mounting holes 22. In certain aspects of the chassis 10, a percentage of a total area of all the output openings to a total area bounded by the chassis 10 is greater than 1.5%. In other aspects of the chassis 10, the percentage of a total area of all the output openings to the total area bounded by the chassis 10 is greater than 2.0%.

As illustrated, the fans 12 are located on a front face 10F of the chassis 10. Although the present chassis 10 has been described as having the fans 12 located in a front face 10F of the chassis 10 and the greatest surface area of openings within the rear face 10R of the chassis 10, the present chassis 10 is not limited in this manner since the location of the greatest surface area of openings within a particular chassis may vary from one configuration of chassis to another.

Although a single fan 12 can be sized to produce the same amount of airflow through the interior of the chassis 10 as the amount of airflow produced by a plurality of fans 12, the use of a plurality of fans 12 (e.g., four fans 12 as shown in FIG. 1A), creates a more even distribution of airflow across a given cross-section of the chassis 10, which also reduces the propensity for hot spots to develop within the interior of the chassis 10. In certain aspects of the chassis 10, a percentage of a total output area of the fans 12 on a particular face 10F of the chassis 10 to the total area of the particular face 10F of the chassis is greater than 18.0%. In other aspects of the chassis 10, the percentage of the total output area of the fans 12 on the particular face 10F of the chassis 10 to the total area of the particular face 10F of the chassis is greater than 24.0%. As this percentage increases, a more uniform airflow through the interior of the chassis 10 may be provided.

Unlike a typical chassis 10, in which the fan(s) 12 are sized (e.g., Cubic Feet per Minute—CFM) primary to cool the internal components within the interior of the chassis 10, the plurality of fans 12 are sized, not only to cool the internal components within the interior of the chassis 10, but also to create a positive pressure differential between the interior of the chassis 10 and the exterior of the chassis 10. Furthermore, the plurality of fans 12 may be sized to create a positive pressure differential at all of the output openings within the chassis 10. In this manner, particulate matter can be prevented from entering the chassis 10. The CFM ratings of the fans 12 are derated to compensate for a filter 28 placed over the fans 12 and any back pressure associated with obstructions within the interior of the chassis 10 or a result of a protective bezel 27 in front of the fans 12. The cumulative CFM rating of all the fans 12 may also be derated for any other fans (e.g., within the power supply 14) that create a negative pressure differential within the chassis 10 (i.e., expel air from the chassis 10).

In certain aspects of the invention, the fans 12 are sized to produce an average velocity of air exiting the chassis 10 that is greater than 9 ft/second. In other aspects of the chassis, the fans 12 are sized to produce an average velocity of air exiting the chassis 10 that is greater than 12 ft/second. The average velocity of air exiting the chassis 10 is a function of (i) the volume of air entering the chassis for a given time period (e.g., the derated cumulative CFM for the fans 12), which given a steady-state condition is also the volume of air exiting the chassis 10 for a given time period, and (ii) the area of output openings within the chassis 10.

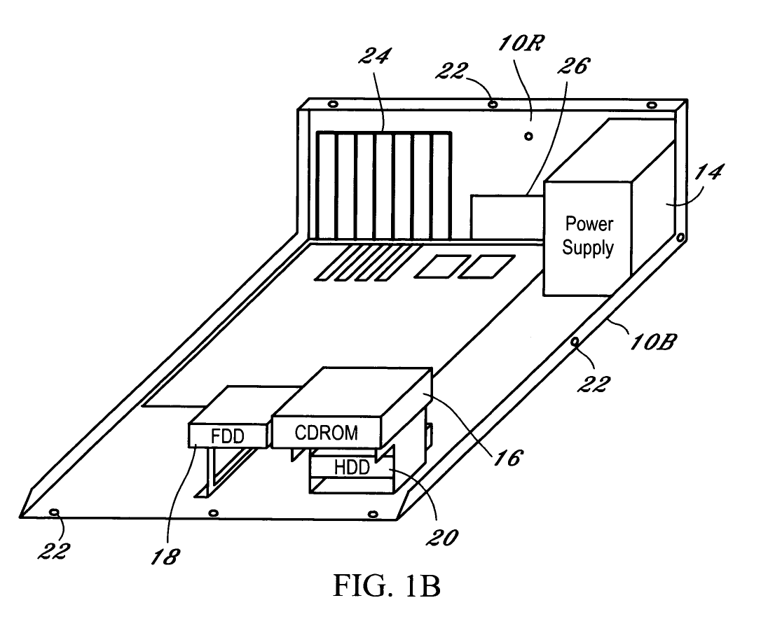

A protective bezel 27 is disposed in front of each of the fans 12, and an enlarged portion of a bezel 27 is illustrated in FIG. 2. As is known to those skilled in the art, a bezel 27 can serve several functions. For example, the bezel 27 protects the fan 12 by preventing large objects (e.g., fingers, pencils) from impinging upon the fan 12, and the bezel 27 can also support a filter 28 disposed over the bezel 27. Any bezel 27 capable of performing any of the above-described functions is acceptable for use with the chassis 10. However, in a current aspect of the chassis 10, the bezel 27 is formed from hexagon-shaped cells. In so doing, the hexagon-shaped cells provide the bezel 27 within additional strength. Also, the hexagon-shaped cells comply with UL/CE (i.e., safety) and FCC (i.e., RF) requirements.

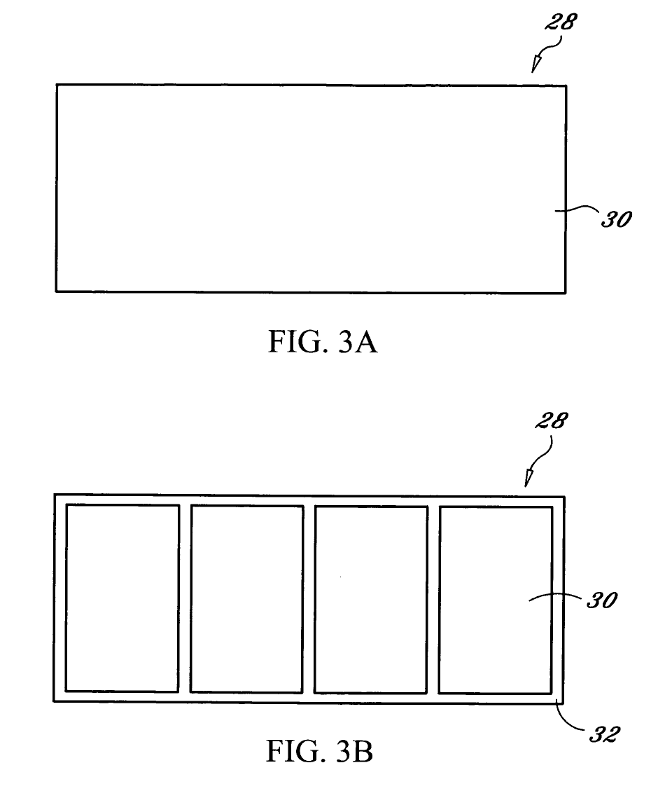

FIGS. 3A and 3B illustrate a filter 28 capable of being used with the chassis 10. Either a combination of filters 28 (not shown) or a single filter 28 may be located over the intake for each of the fans 12. In so doing, all air entering the chassis 10 will be channeled through the filter 28. The filter 28 includes filter material 30 and a frame 32. As is recognized by one skilled in the art, the many types of filter materials are known, and the filter material 30 to be used with the filter 28 may be selected depending upon he particular environment in which the chassis 10 will be used and/or the depending upon the particular particulate matter to be filtered out.

The frame 32 is used to connect the filter 28 to the chassis 10, and any frame 32 capable of connecting the filter 28 to the chassis 10 is acceptable for use with the filter 28. Although not limited in this manner, the frame 32 may be formed from a magnetic material that can magnetically adhere to the chassis 10. The use of magnetic material for the frame 32 allows the filter 28 to be easily removed from the chassis 10 and/or replaced. The frame 32 may also be configured to not interfere with the passage of air into the fans 12 by being positioned away from and at the periphery of the fans 12.

### EXAMPLE

The chassis has a height of 6.25″, a depth of 16.25″, and a width of 17,″ which yields an internal volume of approximately 1 ft³ and a total area bounded by the chassis 10 as 2×((6.25″×16.25″)+(6.25″×17″)+(16.25″×17″)) or 968 in². The area of the output openings of the chassis were determined to be approximately 17.2 in², which is broken down into 509 holes in a rear bezel for 9.72 in², a slot cover of 0.36 in², 4 rack mount screw holes for 0.057 in², and 7.065 in² for a power supply exhaust opening. The percentage of an area (17.2 in²) of all the output openings to the total area (968 in²) bounded by the chassis 10 is 1.8%.

The area of the input openings of the chassis is determined to be approximately 17.73 in², which is broken down into 3 cooling fans having a 3″ diameter with a hexagon bezel covering 16% of the opening. This yields a percentage of an area of the fans on the face to total area of the face of (3*π*(1.5″)²) to (6.25″*17″) or approximately 20.0%. The volume of air through the 3 cooling fans per a given time period is calculated based upon a rated 36.88 CFM per fan. Each fan is derated 60% to compensate for the filter, back pressure, and the bezel over each fan. This yields a total of 66.4 CFM for the 3 cooling fans.

The above-described chassis, therefore, achieved a input opening to output opening ratio of 17.73:17.2 or approximately 1:1. Furthermore, the time to completely replace the internal volume of air within the chassis is calculated to be 1 ft³*(60 seconds/66 * ft³) or approximately 0.9 seconds. The calculated velocity of the air through the output openings is (1 ft³)/((0.9 seconds)*((17.2 in²)*(1 ft² /144 in²))) or approximately 9.3 ft/second.

What is claimed is:

1. A chassis for an electronic device, comprising:
a plurality of fans, each of the fans directing a fluid into an interior of the chassis;
wherein a positive pressure exists between the interior of the chassis and an exterior of the chassis at all output openings within the chassis.

2. The chassis according to claim 1, wherein the plurality of fans are attached to a single face of the chassis.

3. The chassis according to claim 2, wherein
the fluid outputted by the plurality of fans is directed toward a second face of the chassis, and
the second face of the chassis having a greatest total area of the output openings.

4. The chassis according to claim 2, wherein a percentage of a total area of the plurality of fans on the single face to a total area of the single face is greater than 18.0%.

5. The chassis according to claim 2, wherein a percentage of a total area of the plurality of fans on the single face to a total area of the single face is greater than 24.0%.

6. The chassis according to claim 1, wherein an average velocity of the fluid exiting the chassis at the output is greater than 9 ft/second.

7. The chassis according to claim 1, wherein an average velocity of the fluid exiting the chassis at the output opening is greater than 12 ft/second.

8. The chassis according to claim 1, wherein a volume of the interior of the chassis is less than 1.5 ft³.

9. The chassis according to claim 1, wherein a percentage of a total area of all the output openings to a total area bounded by the chassis is greater than 1.5%.

10. The chassis according to claim 1, wherein a percentage of a total area of all the output openings to a total area bounded by the chassis is greater than 2.0%.

11. The chassis according to claim 1, wherein the electronic system is a computer.

12. The chassis according to claim 1, further comprising at least one detachable filter disposed over the plurality of fans.

13. The chassis according to claim 12, further comprising at least one hexagon-shaped bezel is disposed between the plurality of fans and the at least one filter.

14. A chassis for a computer, comprising:
a plurality of fans attached to a single face of the chassis, each of the fans directing a fluid into an interior of the chassis and toward a second face of the chassis; wherein
a positive pressure exists between the interior of the chassis and an exterior of the chassis at all output openings within the chassis,
the second face of the chassis having a greatest total area of the output openings, and
an average velocity of the fluid exiting the chassis at the output openings is greater than 9 ft/second.

15. The chassis according to claim 14, further comprising at least one detachable filter disposed over the plurality of fans.

16. The chassis according to claim 15, further comprising at least one hexagon-shaped bezel is disposed between the plurality of fans and the at least one filter.

17. The chassis according to claim 14, wherein a volume of the interior of the chassis is less than 1.5 ft³.

18. A chassis for a computer, comprising:
a plurality of fans attached to a single face of the chassis, each of the fans directing a fluid into an interior of the chassis and toward a second face of the chassis; wherein
a positive pressure exists between the interior of the chassis and an exterior of the chassis at all output openings within the chassis,
the second face of the chassis having a greatest total area of the output openings, and
a percentage of a total area of the plurality of fans on the single face to a total area of the single face is greater that 18.0%.

19. The chassis according to claim 18, further comprising at least one detachable filter disposed over the plurality of fans.

20. The chassis according to claim 19, further comprising at least one hexagon-shaped bezel is disposed between the plurality of fans and the at least one filter.
